(19) United States
(12) Patent Application Publication
(10) Pub. No.: US 2024/0111076 A1
(43) Pub. Date: Apr. 4, 2024

(54) OPTICAL METASTRUCTURES HAVING META-ATOMS COMPOSED OF A HIGH REFRACTIVE INDEX MATERIAL

(71) Applicant: NILT Switzerland GmbH, Horgen (CH)

(72) Inventors: Maksim Zalkovskij, Copenhagen (DK); Brian Bilenberg, Ølstykke (DK)

(21) Appl. No.: 18/285,818

(22) PCT Filed: Apr. 4, 2022
(86) PCT No.: PCT/EP2022/058888

§ 371 Date: Oct. 5, 2023

Related U.S. Application Data
(60) Provisional application No. 63/171,406, filed on Apr. 6, 2021.

(51) Int. Cl. G02B 1/00; G03F 7/00; G03F 7/20; G03F 7/40

(52) U.S. Cl. CPC G02B 1/002; G03F 7/0005; G03F 7/20; G03F 7/40

(57) ABSTRACT

Metastructures having meta-atoms composed of a high refractive index material are described, as are methods for manufacturing the metastructures. Intermediate wafers that can be produced during the methods also are described.

### FIELD OF THE DISCLOSURE

The present disclosure relates to optical metastructures.

### BACKGROUND

Advanced optical elements may include a metasurface, which refers to a surface with distributed small structures (e.g., meta-atoms) arranged to interact with light in a particular manner. For example, a metasurface, which also may be referred to as a metastructure, can be a surface with a distributed array of nanostructures. The nanostructures may, individually or collectively, interact with light waves. For example, the nanostructures or other meta-atoms may change a local amplitude, a local phase, or both, of an incoming light wave.

When meta-atoms (e.g., nanostructures) of a metasurface are in a particular arrangement, the metasurface may act as an optical element such as a lens, lens array, beam splitter, diffuser, polarizer, bandpass filter, or other optical element. In some instances, metasurfaces may perform optical functions that are traditionally performed by refractive and/or diffractive optical elements. The meta-atoms may be arranged so that the metastructure functions, for example, as a lens, grating coupler, fanout grating, diffuser or other optical element. In some implementations, the metasurfaces may perform other functions, including polarization control, negative refractive index transmission, beam deflection, vortex generation, polarization conversion, optical filtering, and plasmonic optical functions.

### SUMMARY

The present disclosure describes metastructures having meta-atoms composed of a high refractive index material, as well as methods for manufacturing the metastructures. Intermediate wafers that may be produced during the methods also are described.

In particular, this disclosure describes processes that can be used to manufacture, for example, meta-lenses or other optical elements that include an optical metastructure, wafers of meta-lenses or other optical elements that include an optical metastructure, or intermediary wafers that can be used, e.g., to produce meta-lenses or other optical elements that include an optical metastructure. In addition to meta-lenses, the processes can be used to form other optical elements in high-refractive index material, such as diffractive optical elements and diffusers.

In one aspect, for example, the present disclosure describes a method that includes providing a hardmask layer on a layer composed of a high refractive index material, the high refractive index material having a refractive index in a range of 2 to 4, wherein the layer composed of the high refractive index material is supported by a substrate. The method further includes depositing a resist layer on the hardmask layer, and pressing a surface of a tool into the resist layer, wherein the surface of the tool includes features that are imprinted into the resist layer. The tool then is released from the resist layer.

Some implementations include one or more of the following features. For example, in some instances, after releasing the tool form the resist layer, portions of a residual resist layer that is on the hardmask layer are removed, so as to expose first portions of the hardmask layer. In some instances, the portions of the residual resist layer are removed using a directional oxygen plasma.

In some implementations, the method includes selectively etching the hardmask layer to expose first portions of the layer composed of the high refractive index material, and selectively etching the exposed first portions of the layer composed of the high refractive index material to form trenches therein. In some cases, after selectively etching the hardmask layer and selectively etching the exposed first portions of the layer composed of the high refractive index material, remaining portions of the resist layer and the hardmask layer are removed so as to expose second portions of the layer composed of the high refractive index material, wherein the second portions of the layer composed of the high refractive index material define optical meta-atoms on the substrate. In some instances, selectively etching the exposed first portions of the layer composed of the high refractive index material includes using an inductively coupled plasma, wherein remaining portions of the resist layer and the hardmask serve as a mask while etching the layer composed of the high refractive index material.

The disclosure also describes an apparatus including a substrate, a layer composed of a high refractive index material and disposed on the substrate, a hardmask layer disposed on the layer composed of the high refractive index material, and a resist layer disposed on the hardmask layer, wherein the resist layer has features imprinted therein. The high refractive index material has a refractive index in a range of 2 to 4.

In some implementations, the layer composed of the high refractive index material is composed of a material selected from a group consisting of: amorphous silicon, polycrystalline silicon, crystalline silicon, silicon nitride, titanium dioxide, and alumina. In some implementations, the hardmask material is composed of a material selected from a group consisting of: chrome, titanium, aluminum, silicon nitride and silicon dioxide.

The present disclosure also describes a method that includes providing a hardmask layer on a layer composed of a high refractive index material, the high refractive index material having a refractive index in a range of 2 to 4, and the layer composed of the high refractive index material being supported by a substrate. The method further includes depositing a UV resist layer on the hardmask layer, selectively exposing first portions of the UV resist to UV radiation, developing the resist after exposing the first portions of the UV resist to the UV radiation, and selectively removing either the first portions of the UV resist that were exposed to the UV radiation or second portions of the UV resist that were not exposed to the UV radiation.

Some implementations include one or more of the following features. For example, in some instances, the method includes using a deep ultra-violet lithography tool to selectively expose the first portions of the UV resist to the UV radiation. In some cases, the method includes selectively etching the hardmask layer to expose first portions of the layer composed of the high refractive index material, and selectively etching the exposed first portions of the layer composed of the high refractive index material to form trenches therein. In some instances, after selectively etching the hardmask layer and selectively etching the exposed first portions of the layer composed of the high refractive index material, remaining portions of the resist layer and the hardmask layer are removed so as to expose second portions of the layer composed of the high refractive index material, wherein the second portions of the layer composed of the high refractive index material define optical meta-atoms on the substrate.

In some implementations, selectively etching the exposed first portions of the layer composed of the high refractive index material includes using an inductively coupled plasma, wherein remaining portions of the resist layer and the hardmask serve as a mask while etching the layer composed of the high refractive index material.

The disclosure also describes an apparatus including a substrate, a layer composed of a high refractive index material and disposed on the substrate, a hardmask layer disposed on the layer composed of the high refractive index material, and a resist layer disposed on the hardmask layer, wherein the resist layer defines a pattern of features on the hardmask layer. The high refractive index material has a refractive index in a range of 2 to 4.

In some implementations, the layer composed of the high refractive index material is composed of a material selected from a group consisting of: amorphous silicon, polycrystalline silicon, crystalline silicon, silicon nitride, titanium dioxide, and alumina. In some implementations, the hardmask material is composed of a material selected from a group consisting of: chrome, titanium, aluminum, silicon nitride and silicon dioxide.

The disclosure also describes assemblies that can be used as a master/tool/mold, for example, to form metalenses in a polymeric material (e.g., by replication). Other methods and apparatus are described as well.

Other aspects, features and advantages will be apparent form the following detailed description, the accompanying drawings, and the claims.

### BRIEF DESCRIPTION OF THE DRAWINGS

FIGS. 1A through 1J illustrate various steps in a first example process for manufacturing an optical element.

FIGS. 2A through 2K illustrate various steps in a second example process for manufacturing an optical element.

FIGS. 3A through 3J illustrate various steps in a third example process for manufacturing an optical element.

FIGS. 4A through 4H illustrate various steps in a fourth example process for manufacturing an optical element.

FIGS. 5A through 5J illustrate various steps in a fifth example process for manufacturing an optical element.

FIGS. 6A through 6J illustrate various steps in a sixth example process for manufacturing an optical element.

FIGS. 7A through 7H illustrate various steps in a seventh example process for manufacturing an optical element.

FIGS. 8A through 8L illustrate various steps in an eighth example process for manufacturing an optical element.

### DETAILED DESCRIPTION

In some instances, nano-sized structures, such as meta-atoms, can be formed in a material having a relatively low-index of refraction (e.g., a polymeric material having an index of refraction of about 1.5). However, forming the meta-atoms in a relatively high-index material (e.g., a material having a refractive index in the range of 2-4) may be desirable, for example, to achieve improved optical performance. Examples of such high-index materials include inorganic materials, such as amorphous silicon, polycrystalline silicon, crystalline silicon, silicon nitride, titanium dioxide, and alumina, which can be deposited onto a substrate that is transparent to the operating wavelength for the optical element.

The following paragraphs describe various processes that can be used to manufacture, for example, meta-lenses or other optical elements that include an optical metastructure, wafers of meta-lenses or other optical elements that include an optical metastructure, or intermediary wafers that can be used, e.g., to produce meta-lenses or other optical elements that include an optical metastructure. In addition to meta-lenses, the processes can be used to form other optical elements in high-refractive index material, such as diffractive optical elements and diffusers.

In accordance with processes described in greater detail below, features that correspond to a layout or pattern of meta-atoms are formed in a resist layer. Some of the processes use nano-imprint lithography (NIL) to form the features in the resist layer, whereas other processes use deep ultraviolet (DUV) lithography to form the features in the resist layer. In some instances, the lateral resolution of features formed by NIL may be superior to features formed by DUV because tools (e.g., molds) used in NIL can be manufactured using e-beam lithography which has relatively higher lateral resolution. Consequently, in some cases, it may be desirable to use the NIL processes for optical elements intended for shorter operating wavelengths and to use the DUV processes for optical elements intended for longer operating wavelengths. The NIL processes also can be used for optical elements intended for longer operating wavelengths. However, DUV processes generally may be more easily scaled to mass manufacturing processes.

As explained below, some of the processes use hardmasks, which can facilitate etching deep structures because they are highly resistant to etchants. The hardmasks can be, for example, a metal that has good adhesion properties to the high-refractive index layer and that exhibits good etch resistance (i.e., high selectivity). Examples of the hardmask material include chrome, titanium, or aluminum. Silicon nitride or silicon dioxide are other hardmask materials that may be used in some instances.

Using hardmasks in combination with NIL processes can facilitate manufacturing high-aspect ratio meta-atoms because the lateral dimensions are defined by imprinting (which, in turn, is defined by e-beam lithography), and the trench depths are defined by the ability of the hardmasks to resist etching. High-aspect ratio meta-atoms may be desirable in some cases.

In some instances, the substrate has an anti-reflective coating on the side opposite the high-refractive index layer.

The following paragraphs describe particular examples of processes for manufacturing an optical element that includes meta-atoms disposed on a substrate and composed of a material having a high-refractive index (HRI) (i.e., an index of refraction in the range of 2-4).

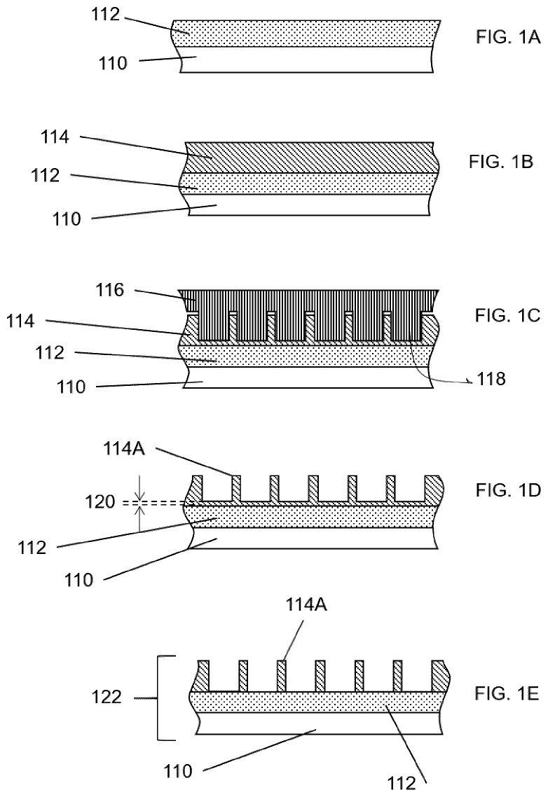

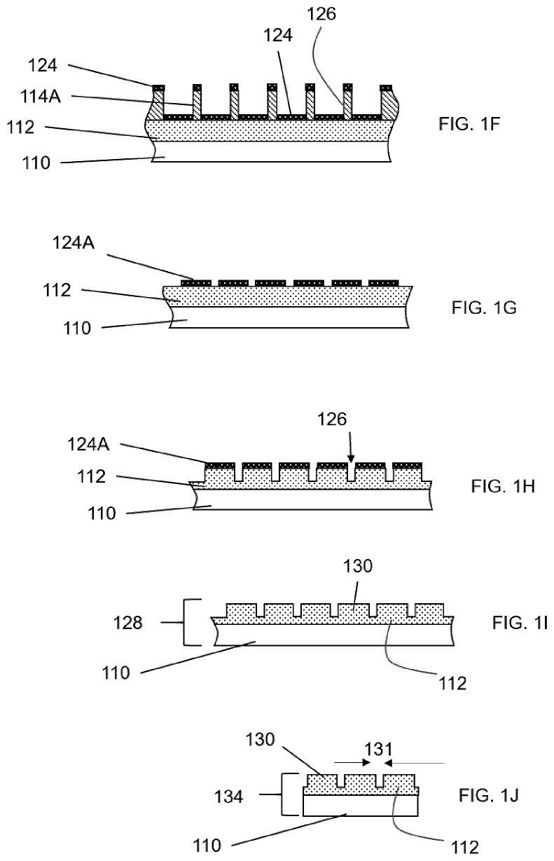

FIGS. 1A through 1J illustrate various steps in a first example process for manufacturing an optical element (e.g., a meta-lens). FIG. 1A shows a substrate 110 (e.g., a glass wafer) having a high-refractive index (HRI) layer 112 deposited on one side of the substrate. The HRI layer has an index of refraction in the range of 2-4. As shown in FIG. 1B, a resist layer 114 is deposited onto the HRI layer 112, for example by spin coating or jetting. If the resist layer 114 is deposited by spin coating, the spin speed can be, for example, in the range of 2000 to 7000 rotations per minute (rpm), depending on the particular resist used and the degree to which the resist is diluted in organic solvent. In some instances, the resist layer 114 is deposited to a final thickness in the range of 50-500 nm. The resist layer 114 can be, for example, a thermal resist (e.g., a thermoplast, such as a plastic polymer, which becomes softer when heated and harder when cooled). After depositing the resist layer 114, it may be heated to drive off excess organic solvent.

Next, the resist layer 114 is heated above it glass transition temperature (Tg) (e.g., 80° C. to 200° C.), and, as shown in FIG. 1C, a tool (e.g. a mold) 116 is pressed into the resist layer. The surface of the tool 116 facing the resist layer 114 includes small nano-features 118 that are imprinted into the resist layer. The resist layer 114 then is allowed to cool below its Tg, and the tool 116 subsequently is released from the resist layer.

As shown in FIG. 1D, after releasing the tool 116 from the resist layer 114, an imprinted resist layer 114A remains on the HRI layer 112. A residual layer 120 having a thickness, for example, of 5 nm to 50 nm also may remain on the surface of the HRI layer 112. Exposed portions of the residual layer 120 are removed, for example, with directional oxygen plasma using a high-vacuum tool or using a barrel asher. Preferably, the portions of the residual layer 120 are removed at a highly controlled rate (e.g., removed at a rate of 0.1 to 5 nm per second). The result, shown in FIG. 1E, is an unfinished, intermediate wafer 122, which includes the imprinted resist layer 114A. In some cases, the intermediate wafer 122 of FIG. 1E (or the intermediate wafer of FIG. 1D) may be transferred to another facility or provided to another fabrication facility for further processing. That is, in some instances, a particular fabrication facility may be able to conduct the nano-imprinting step of FIG. 1C, but not have the capability to process the wafer further into a final optical element or component as described in connection with FIGS. 1F-1J. Further, etching the residual layer also may require sophisticated equipment not readily available to some fabrication facilities. Thus, in some instances, an end (intermediary) product may be an assembly that includes the residual layer.

As shown in FIG. 1F, a hardmask material 124 then is deposited on the exposed upper surfaces of the resist layer 114A and the HRI layer 112. In the illustrated example, a high-vacuum tool can be used to deposit the hardmask material 124 (e.g., deposition can be by e-beam deposition or by thermal deposition with a high-vacuum). The high vacuum enables directional deposition of the hardmask material which is needed so that the sidewalls 126 of the resist layer 114A preferably are not covered in hardmask material.

Next, the resist 114A, along with the portions of the hardmask material 124 that are on the resist, is lifted off. This lift-off process can be performed, for example, in a beaker using a solution such as an organic solvent (e.g., acetone). Sonic/ultrasound can be applied to facilitate the liftoff process. As indicated by FIG. 1G, the portions 124A of the hardmask material that were deposited on the surface of the HRI layer 112 remain even after the lift-off process.

As shown in FIG. 1H, the HRI layer 112 then is etched, for example, using inductively coupled plasma (ICP). The hardmask 124A serves as a mask so that the HRI layer 112 is etched selectively. A high-bias (i.e., highly directional) plasma should be used to obtain trenches 126 having substantially vertical sidewalls in the etched HRI layer 112. In some implementations, if the HRI layer 112 is composed of silicon, then C₄F₈ and SF₆ gasses can be used to etch and passivate the silicon simultaneously. In some instances, a HRI layer 112 composed of silicon can be etched using CHF₃, SF₆ and BCl₃. Other etching techniques can be used for some implementations (e.g., etching with O₂ and SF₆ plasma).

Next, the hardmask 124A is removed, for example, by a high-power oxygen and nitrogen plasma in a barrel asher. FIG. 1I shows an example of the resulting metastructure wafer 128, including the meta-atoms 130 formed in the HRI layer 112. Thus, the meta-atoms 130 are composed of the HRI layer material (i.e., a material having a refractive index in the range or 2-4). Further, by comparing FIG. 1I to FIG. 1E, it is apparent that the lateral width of a resist feature 114A corresponds to the distance 131 separating adjacent meta-atoms 130, and the separation between adjacent resist features 114A corresponds to a lateral dimension of a meta-atom 130.

The metastructure wafer 128 can be separated (e.g., by dicing) into individual optical elements (e.g., metalenses), an example of which is shown in FIG. 1J and identified by reference numeral 134. The individual optical element (e.g., metalens) 134 includes meta-atoms 130, composed of the HRI layer material 112 and supported by the substrate 110. Thus, the meta-atoms 130 of the optical element 134 are composed of a material having a refractive index in the range or 2-4.

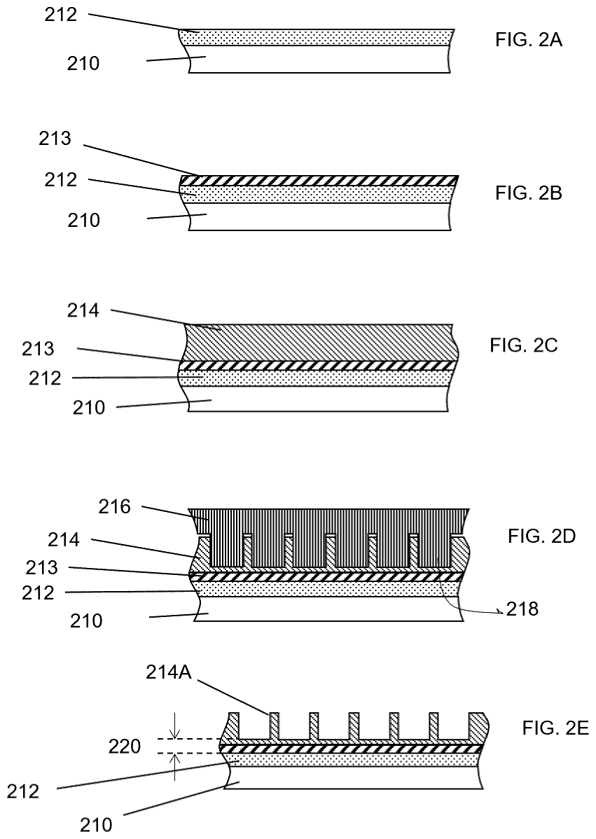

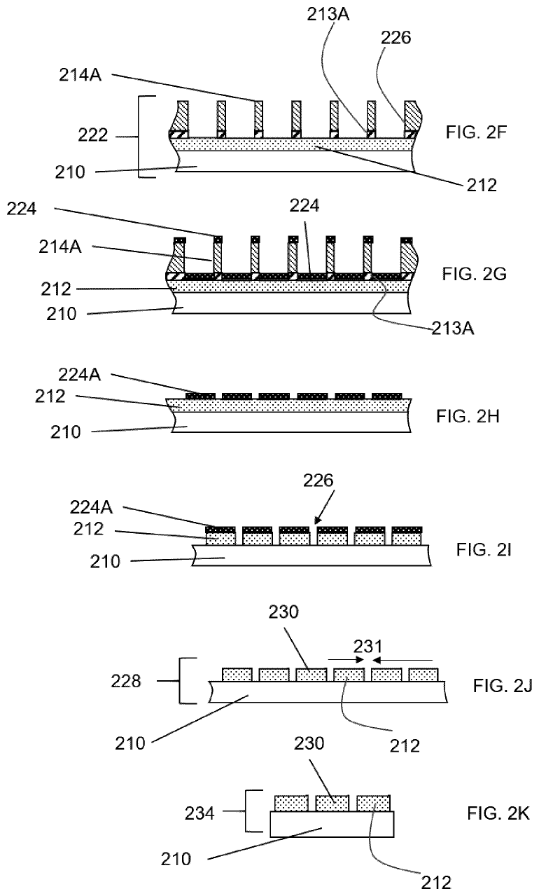

FIGS. 2A through 2K illustrate various steps in a second example process for manufacturing an optical element (e.g., a meta-lens). FIG. 2A shows a substrate 210 (e.g., a glass wafer) having a high-refractive index (HRI) layer 212 deposited on one side of the substrate. The HRI layer has an index of refraction in the range of 2-4. As shown in FIGS. 2B and 2C, respectively, a thin liftoff resist layer 213 is deposited on the HRI layer 212, and a resist layer 214 is deposited on the liftoff layer 213. The resist layer 214 can be, for example, a UV resist that hardens when exposed to ultraviolet (UV) radiation. Using a UV resist for the imprinting can be advantageous in some cases. Typically, there may be a thermal expansion mismatch between the imprinting tool (216 in FIG. 2D) and the substrate 210. If the imprinting were to involve heating, the tool 216 may distort, which could then distort the resulting metastructures. On the other hand, a UV imprint does not require such heating, and thus distortion as a result of heating would not occur.

The liftoff resist 213 can be composed, for example, of a polymeric material that has better dissolution properties than the UV resist 214. The liftoff resist 213 can be dissolved, for example, in an organic solvent such as acetone. As the UV resist 214 may undergo significant crosslinking upon UV exposure, it may be difficult to dissolve it in typical solvents. The liftoff resist layer 213 can be deposited, for example by spin coating. In that case, the spin speed can be, for example, in the range of 2000 to 7000 rotations per minute (rpm), depending on the particular resist used and the degree to which the resist is diluted in organic solvent. The resist layer 213 can be heated to drive off excess organic solvent. In some instances, the resist layer 213 is deposited to a final thickness in the range of 50-200 nm.

In some implementations, the liftoff resist layer 213 can be omitted. However, because the UV resist layer 214 may have relatively high chemical resistance after exposure to UV radiation, it can be advantageous to provide a separate liftoff resist layer 213 to facilitate subsequent processing steps, including removal of the UV resist layer 214.

The UV resist layer 214 can be deposited, for example by spin coating. In that case, the spin speed can be, for example, in the range of 2000 to 7000 rotations per minute (rpm), depending on the particular resist used and the degree to which the resist is diluted in organic solvent. The resist layer 214 can be heated to drive off excess organic solvent. In some instances, the resist layer 214 is deposited to a final thickness in the range of 50-500 nm.

Next, as shown in FIG. 2D, a tool (e.g. a mold) 216 is pressed into the resist layer. The surface of the tool 216 facing the resist layer 214 includes small nano-features 218 that are imprinted into the resist layer. The resist layer 214 then is exposed to UV radiation, and the tool 216 is released from the resist layer.

As shown in FIG. 2E, after the tool 216 is released, a thin residual resist layer 220 remains. In some instances, the thickness of the residual layer 220 consists, for example, of 5 nm to 50 nm of the resist layer 214 plus the thickness of the liftoff resist layer 213. Exposed portions of the residual layer 220, including the liftoff resist layer and UV resist layer are removed, for example, with directional oxygen plasma using a high-vacuum tool or using a barrel asher. The residual layer 220 should be removed at a highly controlled rate (e.g., removed at a rate of 0.1 to 5 nm per second). The result, shown in FIG. 2F, is an unfinished, intermediate wafer 222, which includes the imprinted resist layer 214A and the underlying portions 213A of the liftoff layer. In some cases, the intermediate wafer 222 of FIG. 2F (or the intermediate wafer of FIG. 2E) may be transferred to another facility or provided to another fabrication facility for further processing. That is, in some instances, a particular fabrication facility may be able to conduct the nano-imprinting step of FIG. 2D, but not have the capability to process the wafer further into a final optical element or component as described in connection with FIGS. 2G-2K. Further, etching the residual layer also may require sophisticated equipment not readily available to some fabrication facilities. Thus, in some instances, an end (intermediary) product may be an assembly that includes the residual layer.

As shown in FIG. 2G, a hardmask material 224 then is deposited on the exposed upper surfaces of the resist layer 214A and the HRI layer 212. In the illustrated example, a high-vacuum tool can be used to deposit the hardmask material 224 (e.g., deposition can be by e-beam deposition or by thermal deposition with a high-vacuum). The high vacuum enables directional deposition of the hardmask material which is needed so that the sidewalls 226 of the resist layer 214A preferably are not covered in hardmask material.

Next, the resist layer 214A and 213A, along with the portions of the hardmask material 224 that are on the resist layer, is lifted off. This lift-off process can be performed, for example, in a beaker using a solution such as an organic solvent such as acetone. Sonic/ultrasound can be applied to facilitate the liftoff process. As indicated by FIG. 2H, the portions 224A of the hardmask material that were deposited on the surface of the HRI layer 212 remain even after the lift-off process.

As shown in FIG. 2I, the HRI layer 212 then is etched, for example, using inductively coupled plasma (ICP). The hardmask 224A serves as a mask so that the HRI layer 212 is etched selectively. A high-bias (i.e., highly directional) plasma should be used to obtain trenches 226 having substantially vertical sidewalls in the etched HRI layer 212. In some implementations, if the HRI layer 212 is composed of silicon, then C₄F₈ and SF₆ gasses can be used to etch and passivate the silicon simultaneously. In some instances, a HRI layer 212 composed of silicon can be etched using CHF₃, SF₆ and BCl₃. Other etching techniques can be used for some implementations (e.g., etching with O₂ and SF₆ plasma).

Next, the hardmask 224A is removed, for example, by a high-power oxygen and nitrogen plasma in a barrel asher. FIG. 2J shows an example of the resulting metastructure wafer 228, including the meta-atoms 230 formed in the HRI layer 212. Thus, the meta-atoms 230 are composed of the HRI layer material (i.e., a material having a refractive index in the range or 2-4). Further, by comparing FIG. 2J to FIG. 2F, it is apparent that the lateral width of a resist feature 214A corresponds to the distance 231 separating adjacent meta-atoms 230, and the distance separating adjacent resist features 214A corresponds to a lateral dimension of a meta-atom 230.

The metastructure wafer 228 can be separated (e.g., by dicing) into individual optical elements (e.g., metalenses), an example of which is shown in FIG. 2K and identified by reference numeral 234. The individual optical element (e.g., metalens) 234 includes meta-atoms 230, composed of the HRI layer material 212 and supported by the substrate 210. Thus, the meta-atoms 230 of the optical element 234 are composed of a material having a refractive index in the range or 2-4.

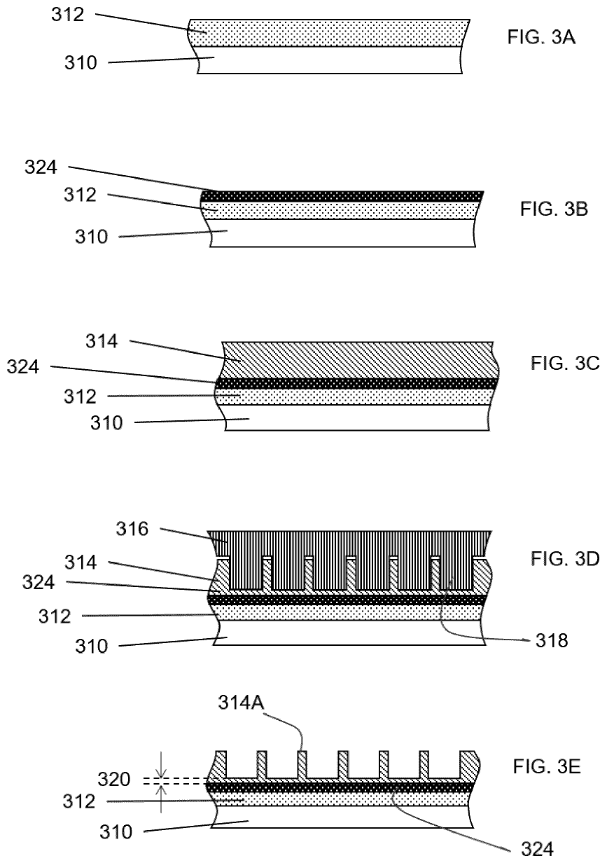

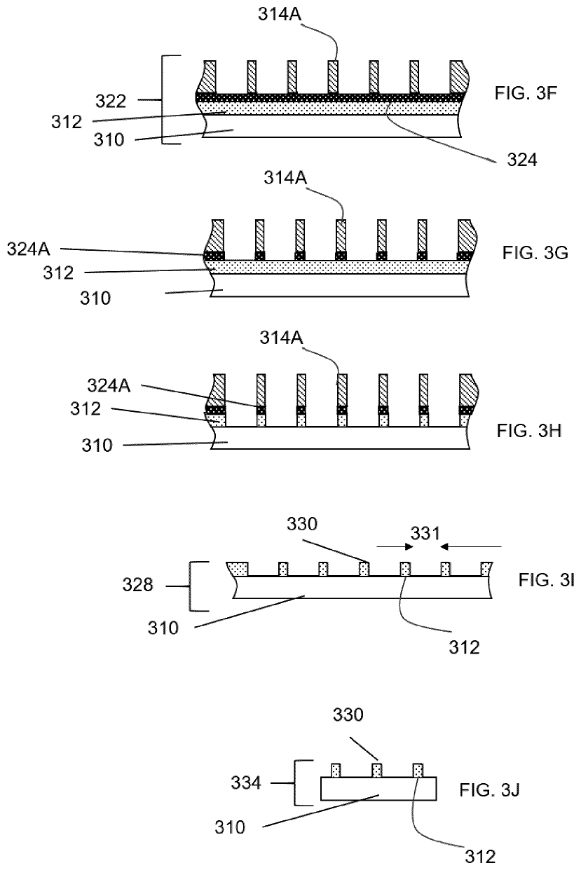

FIGS. 3A through 3J illustrate various steps in a third example process for manufacturing an optical element (e.g., a meta-lens). FIG. 3A shows a substrate 310 (e.g., a glass wafer) having a high-refractive index (HRI) layer 312 deposited on one side of the substrate. The HRI layer has an index of refraction in the range of 2-4. As shown in FIG. 3B, a hardmask layer 324 is deposited onto the HRI layer 312. In this case, a high-vacuum tool is not needed for the hardmask deposition. In particular (in contrast to the first and second processes described above in connection with FIGS. 1A-1J and 2A-2K), there is no need at this stage to avoid covering side walls with the hardmask material. Thus, directional deposition of the hardmask material is not needed in this process of FIGS. 3A-3J. Consequently, the process can be carried out, for example, using sputtering.

Next, as shown in FIG. 3C, a resist layer 314 is deposited onto the hardmask layer 324, for example, by either spin coating or jetting. If the resist layer 314 is deposited by spin coating, the spin speed can be, for example, in the range of 2000 to 7000 rotations per minute (rpm), depending on the particular resist used and the degree to which the resist is diluted in organic solvent. The resist layer 314 can be heated to drive off excess organic solvent. In some instances, the resist layer 314 is deposited to a final thickness in the range of 50-500 nm. The resist layer can be, for example, a thermal resist (as described in the first process) or a UV resist (as described in the second process).

Next, as shown in FIG. 3D, a tool (e.g. a mold) 316 is pressed into the resist layer 314. The surface of the tool 316 facing the resist layer 314 includes small nano-features 318 that are imprinted into the resist layer. The resist 314 then can be hardened. For example, if a thermal resist is used, the resist layer 314 can be heated above it glass transition temperature before, and then allowed to cool before the tool 316 is released from the resist layer. If a UV resist is used, then the resist layer 314 can be exposed to UV radiation before the tool 316 is released from the resist layer.

As shown in FIG. 3E, after the tool 316 is released, a thin residual resist layer 320 remains. In some instances, the thickness of the residual layer 320 is in the range of 5 nm to 50 nm. Exposed portions of the residual layer 320 are removed, for example, with directional oxygen plasma using a high-vacuum tool or using a barrel asher. The residual layer 320 should be removed at a highly controlled rate (e.g., removed at a rate of 0.1 to 5 nm per second). The result, shown in FIG. 3F, is an unfinished, intermediate wafer 322, which includes the imprinted resist layer 314A, as well as the hardmask layer 324. In some cases, the intermediate wafer 322 of FIG. 3F (or the wafer of FIG. 3E) may be transferred to another facility or provided to another fabrication facility for further processing. That is, in some instances, a particular fabrication facility may be able to conduct the nano-imprinting step of FIG. 3D, but not have the capability to process the wafer further into a final optical element or component as described in connection with FIGS. 3G-3J. Further, etching the residual layer also may require sophisticated equipment not readily available to some fabrication facilities. Thus, in some instances, an end (intermediary) product may be an assembly that includes the residual layer.

Next, the hardmask layer 324 is etched, for example, using chlorine and oxygen plasma. The resist layer 314A serves as a mask so that the hardmask layer 324 is etched selectively. Etching the hardmask layer results in a hardmask 324A, as shown in FIG. 3G. In contrast to the liftoff process described in connection with FIGS. 2A-2K, etching the hardmask can, in some cases, be advantageous because it leaves fewer artifacts such as particles and other contaminants.

Then, as shown in FIG. 3H, the HRI layer 312 is etched, for example, using inductively coupled plasma (ICP). The resist layer 314A and the hardmask 324A serve as a mask so that the HRI layer 312 is etched selectively. A high-bias (i.e., highly directional) plasma should be used to obtain trenches 326 having substantially vertical sidewalls in the etched HRI layer 312. In some implementations, if the HRI layer 312 is composed of silicon, then C₄F₈ and SF₆ gasses can be used to etch and passivate the silicon simultaneously. In some instances, a HRI layer 312 composed of silicon can be etched using CHF₃, SF₆ and BCl₃. Other etching techniques can be used for some implementations (e.g., etching with O₂ and SF₆ plasma).

Next, the hardmask 324A and resist 314A that remain on the HRI layer 312 are removed, for example, by a high-power oxygen and nitrogen plasma in a barrel asher. FIG. 3I shows an example of the resulting metastructure wafer 328, including the meta-atoms 330 formed in the HRI layer 312. Thus, the meta-atoms 330 are composed of the HRI layer material (i.e., a material having a refractive index in the range or 2-4).

The metastructure wafer 328 can be separated (e.g., by dicing) into individual optical elements (e.g., metalenses), an example of which is shown in FIG. 3J and identified by reference numeral 334. The individual optical element (e.g., metalens) 334 includes meta-atoms 330, composed of the HRI layer material 312 and supported by the substrate 310. Thus, the meta-atoms 330 of the optical element 334 are composed of a material having a refractive index in the range or 2-4. Further, by comparing FIG. 3I to FIG. 3F, it is apparent that the lateral width of a resist feature 314A corresponds to a lateral dimension of a meta-atom 330, and the distance separating adjacent resist features 314A corresponds to the distance 331 separating adjacent meta-atoms 330.

The foregoing process illustrated by FIGS. 3A-3J can provide various advantages in some implementations. For example, only one layer of resist is needed even when a UV resist is used. Further, the hardmask 324A is defined by etching and not a liftoff process (see FIG. 3G). Etching the hardmask can result in higher quality edge definition for the meta-atoms. Further, the process steps after the imprinting (i.e., after FIG. 3D) can be done in the same processing chamber, which can help facilitate mass production. Also, the residual layer removal step permits precise removal of resist material (see FIG. 3F). Consequently, meta-atom lateral dimensions that are smaller than what can be achieved with some e-beam and NIL processes are possible.

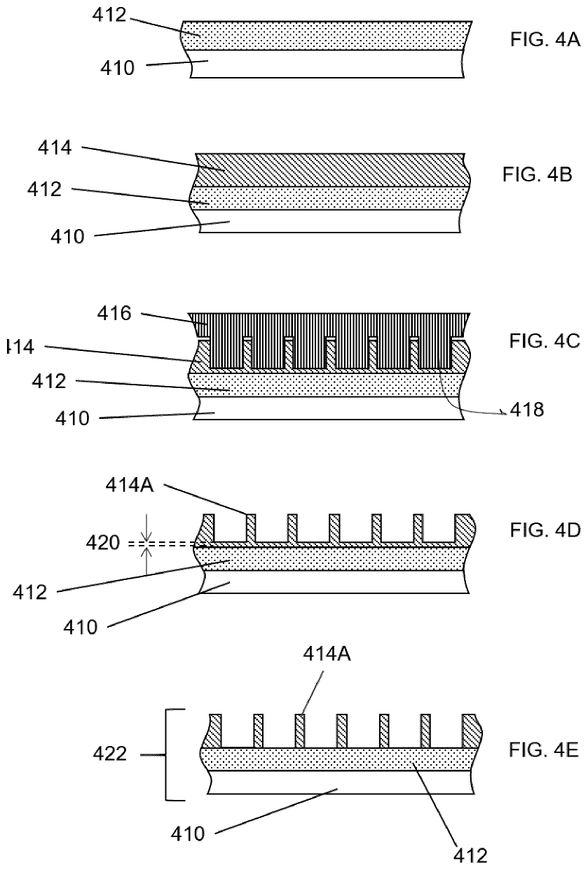

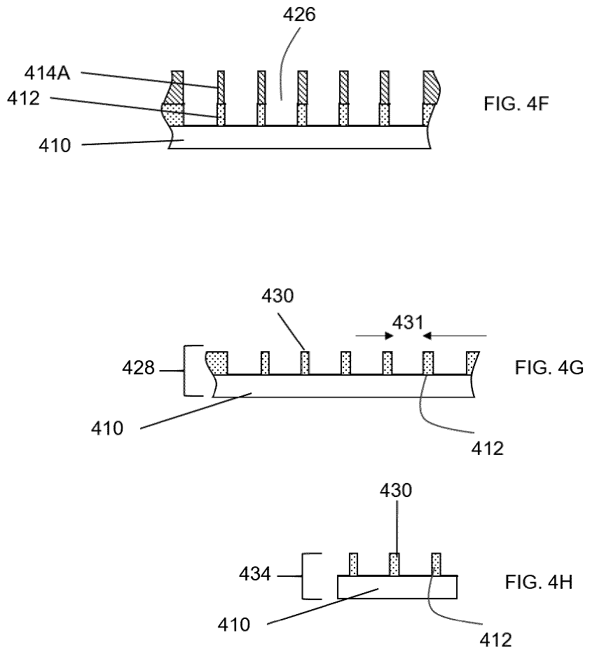

FIGS. 4A through 4J illustrate various steps in a fourth example process for manufacturing an optical element (e.g., a meta-lens). The process steps associated with FIGS. 4A-4E can be the substantially the same as the process steps described in connection with FIGS. 1A-1E. However, the process of FIGS. 4A-4J does not require use of a hardmask and does not require use of liftoff.

FIG. 4A shows a substrate 410 (e.g., a glass wafer) having a high-refractive index (HRI) layer 412 deposited on one side of the substrate. The HRI layer has an index of refraction in the range of 2-4. As shown in FIG. 4B, a resist layer 414 is deposited onto the HRI layer 412, for example by spin coating or jetting. If the resist layer 414 is deposited by spin coating, the spin speed can be, for example, in the range of 2000 to 7000 rotations per minute (rpm), depending on the particular resist used and the degree to which the resist is diluted in organic solvent. In some instances, the resist layer 414 is deposited to a final thickness in the range of 50-500 nm. The resist layer can be, for example, a thermal resist (as described in the first process) or a UV resist (as described in the second process).

Next, as shown in FIG. 4C, a tool (e.g. a mold) 416 is pressed into the resist layer 414. The surface of the tool 416 facing the resist layer 414 includes small nano-features 418 that are imprinted into the resist layer. If a thermal resist is used, the resist layer 414 can be heated above it glass transition temperature before, and then allowed to cool before the tool 416 is released from the resist layer. If a UV resist is used, then the resist layer 414 can be exposed to UV radiation before the tool 416 is released from the resist layer.

As shown in FIG. 4D, after releasing the tool 416 from the resist layer 414, an imprinted resist layer 414A remains on the HRI layer 412. A residual layer 420 having a thickness, for example, of 5 nm to 50 nm also may remain on the surface of the HRI layer 412. Exposed portions of the residual layer 420 are removed, for example, with directional oxygen plasma using a high-vacuum tool or using a barrel asher. Preferably, the portions of the residual layer 420 are removed at a highly controlled rate (e.g., removed at a rate of 0.1 to 5 nm per second). The result, shown in FIG. 4E, is an unfinished, intermediate wafer 422, which includes the imprinted resist layer 414A. In some cases, the intermediate wafer 422 of FIG. 4E (or the intermediate wafer of FIG. 4D) may be transferred to another facility or provided to another fabrication facility for further processing. That is, in some instances, a particular fabrication facility may be able to conduct the nano-imprinting step of FIG. 4C, but not have the capability to process the wafer further into a final optical element or component as described in connection with FIGS. 4F-4H. Further, etching the residual layer also may require sophisticated equipment not readily available to some fabrication facilities. Thus, in some instances, an end (intermediary) product may be an assembly that includes the residual layer.

As shown in FIG. 4F, the HRI layer 412 is etched, for example, using inductively coupled plasma (ICP). The resist layer 414A serves as a mask so that the HRI layer 412 is etched selectively. A high-bias (i.e., highly directional) plasma should be used to obtain trenches 426 having substantially vertical sidewalls in the etched HRI layer 412. In some implementations, if the HRI layer 412 is composed of silicon, then C₄F₈ and SF₆ gasses can be used to etch and passivate the silicon simultaneously. In some instances, a HRI layer 412 composed of silicon can be etched using CHF₃, SF₆ and BCl₃. Other etching techniques can be used for some implementations (e.g., etching with O₂ and SF₆ plasma).

The portions 414A of the resist layer can be removed, for example, by a high-power oxygen and nitrogen plasma in a barrel asher. FIG. 4G shows an example of the resulting metastructure wafer 428, including the meta-atoms 430 formed in the HRI layer 412. Thus, the meta-atoms 430 are composed of the HRI layer material (i.e., a material having a refractive index in the range or 2-4). Further, by comparing FIG. 4G to FIG. 4E, it is apparent that the lateral width of a resist feature 414A corresponds to a lateral dimension of a meta-atom 430, and the distance separating adjacent resist features 414A corresponds to the distance 431 separating adjacent meta-atoms 430.

The metastructure wafer 428 can be separated (e.g., by dicing) into individual optical elements (e.g., metalenses), an example of which is shown in FIG. 4H and identified by reference numeral 434. The individual optical element (e.g., metalens) 434 includes meta-atoms 430, composed of the HRI layer material 412 and supported by the substrate 410. Thus, the meta-atoms 430 of the optical element 434 are composed of a material having a refractive index in the range or 2-4.

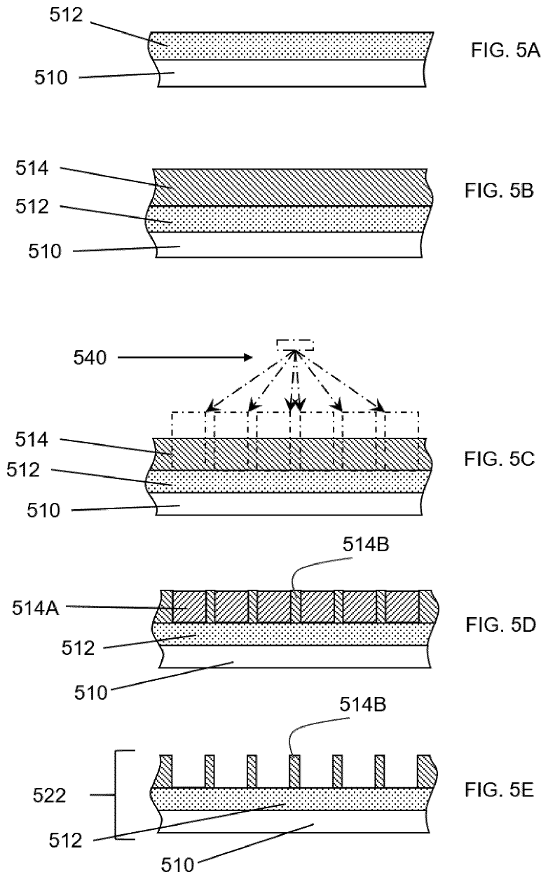

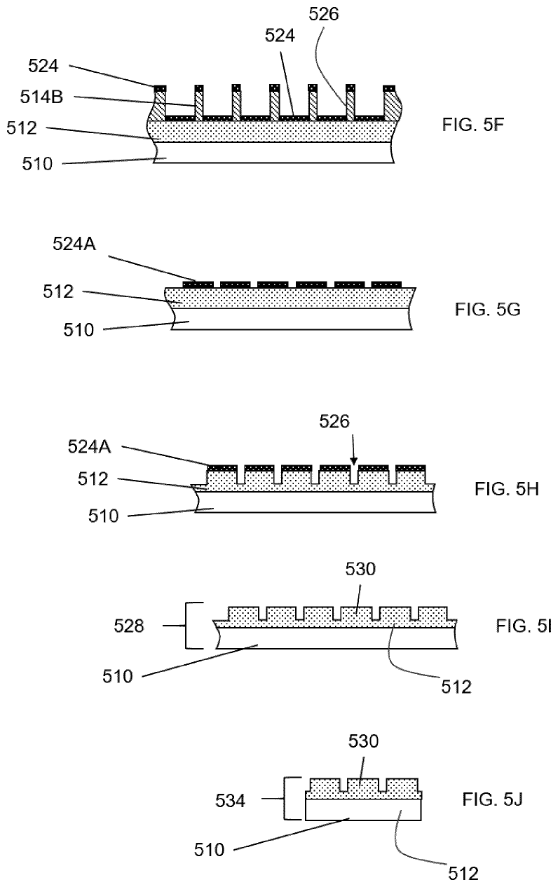

FIGS. 5A through 5J illustrate various steps in a fifth example process for manufacturing an optical element (e.g., a meta-lens). In contrast to the first through the fourth examples above, this fifth process uses deep ultraviolet (DUV) lithography instead of nano-imprint lithography (NIL) to form the features in a resist layer.

FIG. 5A shows a substrate 510 (e.g., a glass wafer) having a high-refractive index (HRI) layer 512 deposited on one side of the substrate. The HRI layer has an index of refraction in the range of 2-4. As shown in FIG. 5B, a UV resist layer 514 is deposited onto the HRI layer 512, for example, by spin coating. The spin speed can be, for example, in the range of 2000 to 7000 rotations per minute (rpm), depending on the particular resist used and the degree to which the resist is diluted in organic solvent. In some instances, the resist layer 514 is deposited to a final thickness in the range of 50-500 nm. The UV resist layer 514 can be a resist that hardens when exposed to ultraviolet (UV) radiation.

Next, as shown in FIG. 5C, portions of the resist layer 514 are exposed to UV radiation using a DUV tool 540. FIG. 5D indicates portions 514A of the resist 514 that are exposed to the UV radiation, and portions 514B that are unexposed. In this example process, there is no residual resist layer as occurs in some of the previous examples described above. The resist layer 514 then is developed using, for example, a suitable solvent, such that the exposed portions 514A are removed. The result, shown in FIG. 5E, is an unfinished, intermediate wafer 522, which includes a pattern of resist (e.g., the unexposed portions 514B of the resist layer 514). Depending on the type of resist, in some instances, unexposed portions of the resist are removed instead of the exposed portions. In such cases, the DUV tool 540 should be configured to expose regions of the resist layer that remain after the resist is developed.

In some cases, the intermediate wafer 522 of FIG. 5E may be transferred to another facility or provided to another fabrication facility for further processing. That is, in some instances, a particular fabrication facility may be able to conduct the DUV lithography step of FIG. 5C, but not have the capability to process the wafer further into a final optical element or component as described in connection with FIGS. 5F-5J.

The process steps associated with FIGS. 5F-5H can be substantially the same as the process steps described in connection with FIGS. 1F-1H. As shown in FIG. 5F, a hardmask material 524 is deposited on the exposed upper surfaces of the HRI layer 512 and on the resist layer material 514B. In the illustrated example, a high-vacuum tool can be used to deposit the hardmask material 524 (e.g., deposition can be by e-beam deposition or by thermal deposition with a high-vacuum). The high vacuum enables directional deposition of the hardmask material which is needed so that the sidewalls 526 of the resist layer material 514B preferably are not covered in hardmask material.

Next, the resist layer material 514B, along with the portions of the hardmask material 524 that are on the resist layer material, are lifted off. This lift-off process can be performed, for example, in a beaker using a solution such as an organic solvent (e.g., acetone). Sonic/ultrasound can be applied to facilitate the liftoff process. As indicated by FIG. 5G, the portions 524A of the hardmask material that were deposited on the surface of the HRI layer 512 remain even after the lift-off process.

As shown in FIG. 5H, the HRI layer 512 then is etched, for example, using inductively coupled plasma (ICP). The hardmask 524A serves as a mask so that the HRI layer 312 is etched selectively. A high-bias (i.e., highly directional) plasma should be used to obtain trenches 526 having substantially vertical sidewalls in the etched HRI layer 512. In some implementations, if the HRI layer 512 is composed of silicon, then C₄F₈ and SF₆ gasses can be used to etch and passivate the silicon simultaneously. In some instances, a HRI layer 512 composed of silicon can be etched using CHF₃, SF₆ and BCl₃. Other etching techniques can be used for some implementations (e.g., etching with O₂ and SF₆ plasma).

Next, the hardmask 524A is removed, for example, by a high-power oxygen and nitrogen plasma in a barrel asher. FIG. 5I shows an example of the resulting metastructure wafer 528, including the meta-atoms 530 formed in the HRI layer 512. Thus, the meta-atoms 530 are composed of the HRI layer material (i.e., a material having a refractive index in the range or 2-4).

The metastructure wafer 528 can be separated (e.g., by dicing) into individual optical elements (e.g., metalenses), an example of which is shown in FIG. 5J and identified by reference numeral 534. The individual optical element (e.g., metalens) 534 includes meta-atoms 530, composed of the HRI layer material 512 and supported by the substrate 510. Thus, the meta-atoms 530 of the optical element 534 are composed of a material having a refractive index in the range or 2-4. Further, by comparing FIG. 5I to FIG. 5E, it is apparent that the lateral width of a resist feature 514B corresponds to the distance 531 separating adjacent meta-atoms 530, and the distance separating adjacent resist features 514B corresponds to a lateral dimension of a meta-atom 530.

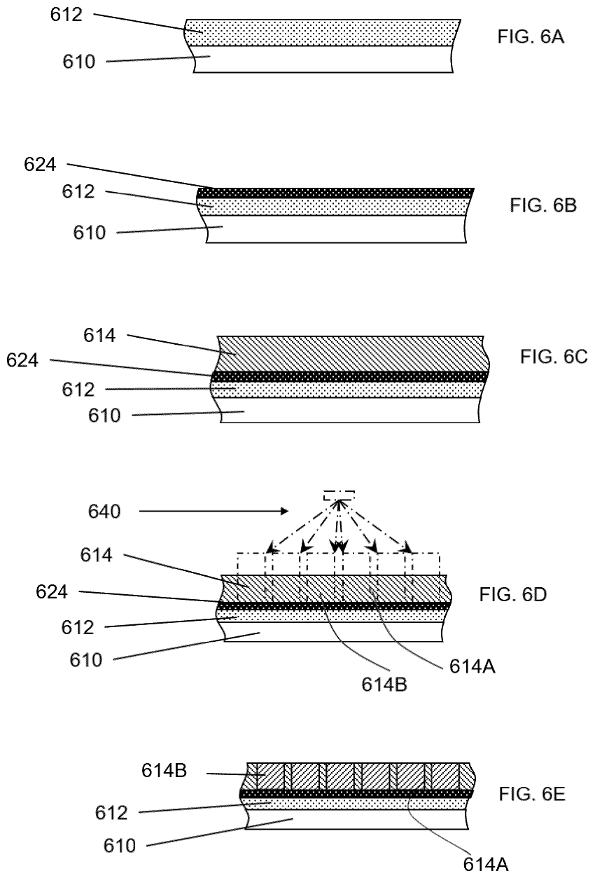

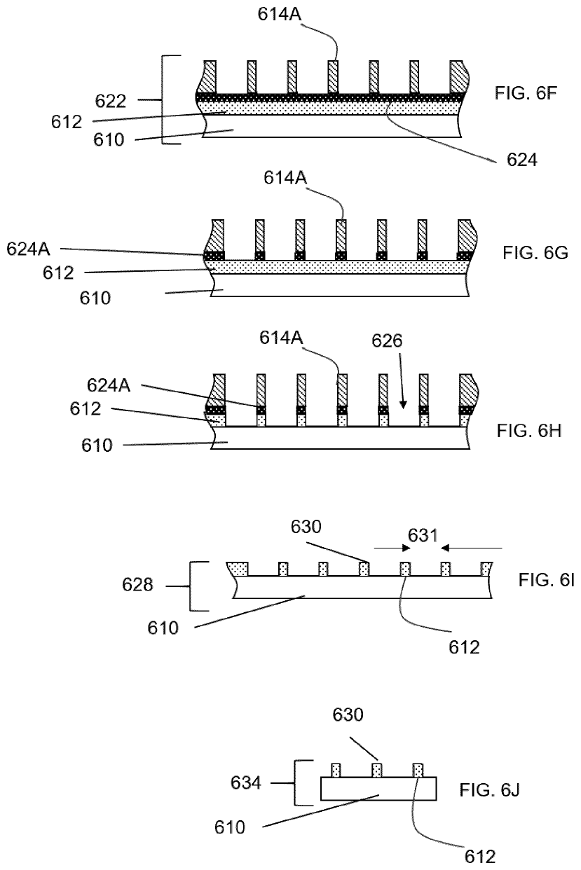

FIGS. 6A through 6J illustrate various steps in a sixth example process for manufacturing an optical element (e.g., a meta-lens). This sixth process uses deep ultraviolet (DUV) lithography to form features in a UV resist layer. The process steps associated with FIGS. 6A-6C can be substantially the same as the process steps associated with FIGS. 3A-3C. Likewise, the process steps associated with FIGS. 6G-6H can be substantially the same as the process steps associated with FIGS. 3G-3H.

FIG. 6A shows a substrate 610 (e.g., a glass wafer) having a high-refractive index (HRI) layer 612 deposited on one side of the substrate. The HRI layer has an index of refraction in the range of 2-4. As shown in FIG. 6B, a hardmask layer 624 is deposited onto the HRI layer 612. A high-vacuum tool is not needed for the hardmask deposition because directional deposition of the hardmask material is not needed in this process of FIGS. 6A-6J. Consequently, the process can be carried out, for example, using sputtering.

Next, as shown in FIG. 6C, a UV resist layer 614 is deposited onto the hardmask layer 624, for example, by spin coating. The spin speed can be, for example, in the range of 2000 to 7000 rotations per minute (rpm), depending on the particular resist used and the degree to which the resist is diluted in organic solvent. The resist layer 614 can be heated to drive off excess organic solvent. In some instances, the resist layer 614 is deposited to a final thickness in the range of 50-500 nm.

Next, as shown in FIG. 6D, portions of the resist layer 614 are exposed to UV radiation using a DUV tool 640. FIG. 6E indicates portions 614A of the resist 614 that are exposed to the UV radiation, and portions 614B that are unexposed. In this example process, there is no residual resist layer as occurs in some of the previous examples described above. The resist layer 614 then is developed using, for example, a suitable solvent, such that the exposed portions 614A are removed. The result, shown in FIG. 6F, is an unfinished, intermediate wafer 622, which includes a pattern of resist (e.g., the unexposed portions 614B of the resist layer 614). Depending on the type of resist, in some instances, unexposed portions of the resist are removed instead of the exposed portions. In such cases, the DUV tool 640 should be configured to expose regions of the resist layer that remain after the resist is developed. The UV resist layer 614 can be a resist that hardens when exposed to ultraviolet (UV) radiation.

In some cases, the intermediate wafer 622 of FIG. 6F may be transferred to another facility or provided to another fabrication facility for further processing. That is, in some instances, a particular fabrication facility may be able to conduct the DUV lithography step of FIG. 6D, but not have the capability to process the wafer further into a final optical element or component as described in connection with FIGS. 6F-6J.

Next, the hardmask layer 624 is etched, for example, using chlorine and oxygen plasma. The resist layer 614B serves as a mask so that the HRI layer 612 is etched selectively. Etching the hardmask layer results in a hardmask 624A, as shown in FIG. 6G. Etching the hardmask (instead, for example, of using a liftoff process) can, in some cases, be advantageous because it leaves fewer artifacts such as particles and other contaminants.

Then, as shown in FIG. 6H, the HRI layer 612 is etched, for example, using inductively coupled plasma (ICP). The resist layer 614B and the hardmask 624A serve as a mask so that the HRI layer 612 is etched selectively. A high-bias (i.e., highly directional) plasma should be used to obtain trenches 626 having substantially vertical sidewalls in the etched HRI layer 612. In some implementations, if the HRI layer 612 is composed of silicon, then C₄F₈ and SF₆ gasses can be used to etch and passivate the silicon simultaneously. In some instances, a HRI layer 612 composed of silicon can be etched using CHF₃, SF₆ and BCl₃. Other etching techniques can be used for some implementations (e.g., etching with O₂ and SF₆ plasma).

Next, the hardmask material 624A and the resist layer material 614B that remain on the HRI layer 612 are removed, for example, by a high-power oxygen and nitrogen plasma in a barrel asher. FIG. 6I shows an example of the resulting metastructure wafer 628, including the meta-atoms 630 formed in the HRI layer 612. Thus, the meta-atoms 630 are composed of the HRI layer material (i.e., a material having a refractive index in the range or 2-4).

The metastructure wafer 628 can be separated (e.g., by dicing) into individual optical elements (e.g., metalenses), an example of which is shown in FIG. 6J and identified by reference numeral 634. The individual optical element (e.g., metalens) 634 includes meta-atoms 630, composed of the HRI layer material 612 and supported by the substrate 610. Thus, the meta-atoms 630 of the optical element 634 are composed of a material having a refractive index in the range or 2-4. Further, by comparing FIG. 6I to FIG. 6F, it is apparent that the lateral width of a resist feature 614B corresponds to a lateral dimension of a meta-atom 630, and the distance separating adjacent resist features 614B corresponds to the distance 631 separating adjacent meta-atoms 630.

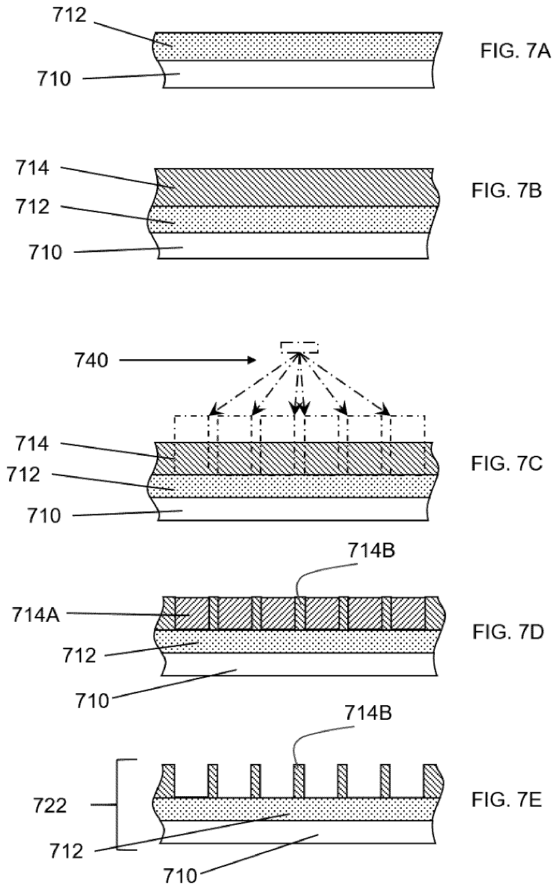

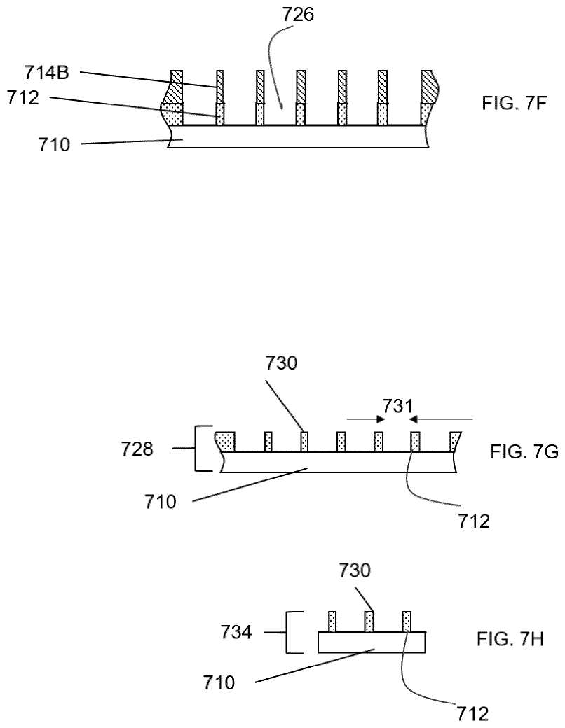

FIGS. 7A through 7H illustrate various steps in a seventh example process for manufacturing an optical element (e.g., a meta-lens). This seventh process uses deep ultraviolet (DUV) lithography to form features in a UV resist layer. The process steps associated with FIGS. 7A-7D can be substantially the same as the process steps associated with FIG. 5A-5D. Likewise, the process steps associated with FIG. 7F can be substantially the same as the process steps associated with FIG. 4F.

FIG. 7A shows a substrate 710 (e.g., a glass wafer) having a high-refractive index (HRI) layer 712 deposited on one side of the substrate. The HRI layer has an index of refraction in the range of 2-4. As shown in FIG. 7B, a UV resist layer 714 is deposited onto the HRI layer 712, for example, by spin coating. The spin speed can be, for example, in the range of 2000 to 7000 rotations per minute (rpm), depending on the particular resist used and the degree to which the resist is diluted in organic solvent. In some instances, the resist layer 714 is deposited to a final thickness in the range of 50-500 nm.

Next, as shown in FIG. 7C, portions of the resist layer 714 are exposed to UV radiation using a DUV tool 740. FIG. 7D indicates portions 714A of the resist 714 that are exposed to the UV radiation, and portions 714B that are unexposed. In this example process, there is no residual resist layer as occurs in some of the previous examples described above. The resist layer 714 then is developed using, for example, a suitable solvent, such that the exposed portions 714A are removed. The result, shown in FIG. 7E, is an unfinished, intermediate wafer 722, which includes a pattern of resist (e.g., the unexposed portions 714B of the resist layer 714). Depending on the type of resist, in some instances, unexposed portions of the resist are removed instead of the exposed portions. In such cases, the DUV tool 740 should be configured to expose regions of the resist layer that remain after the resist is developed. The UV resist layer 714 can be a resist that hardens when exposed to ultraviolet (UV) radiation.

In some cases, the intermediate wafer 722 of FIG. 7E may be transferred to another facility or provided to another fabrication facility for further processing. That is, in some instances, a particular fabrication facility may be able to conduct the DUV lithography step of FIG. 7C, but not have the capability to process the wafer further into a final optical element or component as described in connection with FIGS. 7F-7J. Further, etching the residual layer also may require sophisticated equipment not readily available to some fabrication facilities. Thus, in some instances, an end (intermediary) product may be an assembly that includes the residual layer.

As shown in FIG. 7F, the HRI layer 712 is etched, for example, using inductively coupled plasma (ICP). The resist layer material 714B serves as a mask so that the HRI layer 712 is etched selectively. A high-bias (i.e., highly directional) plasma should be used to obtain trenches 726 having substantially vertical sidewalls in the etched HRI layer 412. In some implementations, if the HRI layer 712 is composed of silicon, then C₄F₈ and SF₆ gasses can be used to etch and passivate the silicon simultaneously. In some instances, a HRI layer 712 composed of silicon can be etched using CHF₃, SF₆ and BCl₃. Other etching techniques can be used for some implementations (e.g., etching with O₂ and SF₆ plasma).

The portions 714B of the resist layer can be removed, for example, by a high-power oxygen and nitrogen plasma in a barrel asher. FIG. 7G shows an example of the resulting metastructure wafer 728, including the meta-atoms 730 formed in the HRI layer 712. Thus, the meta-atoms 730 are composed of the HRI layer material (i.e., a material having a refractive index in the range or 2-4). Further, by comparing FIG. 7G to FIG. 7E, it is apparent that the lateral width of a resist feature 714B corresponds to a lateral dimension of a meta-atom 730, and the distance separating adjacent resist features 714B corresponds to the distance 731 separating adjacent meta-atoms 730.

The metastructure wafer 428 can be separated (e.g., by dicing) into individual optical elements (e.g., metalenses), an example of which is shown in FIG. 7H and identified by reference numeral 734. The individual optical element (e.g., metalens) 734 includes meta-atoms 730, composed of the HRI layer material 712 and supported by the substrate 710. Thus, the meta-atoms 730 of the optical element 734 are composed of a material having a refractive index in the range or 2-4.

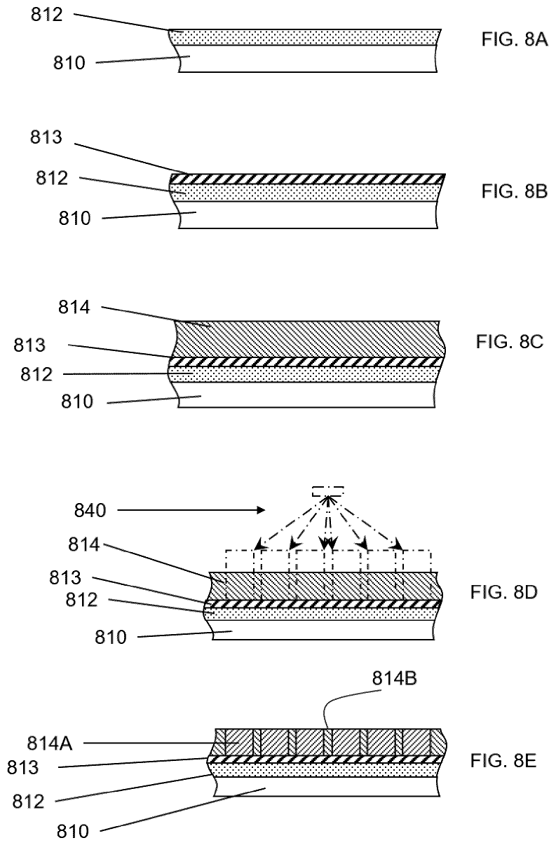

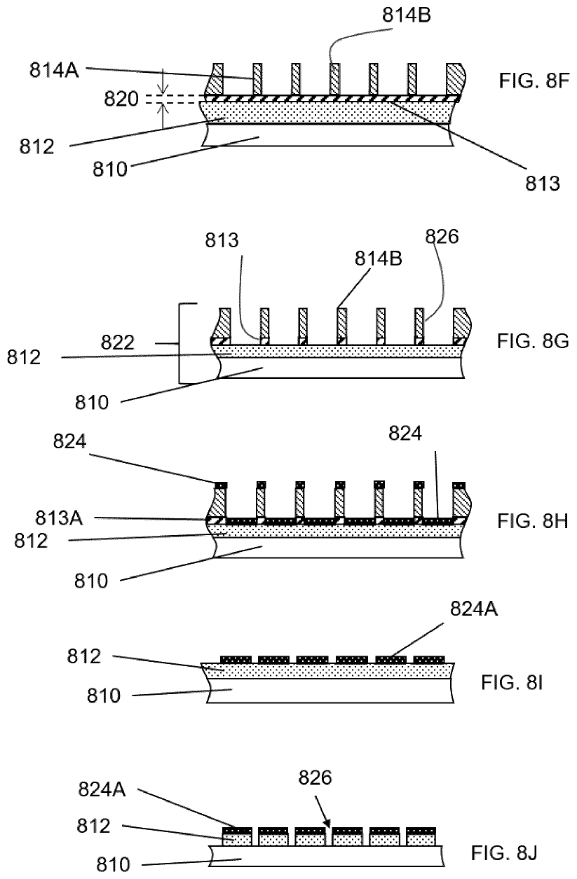

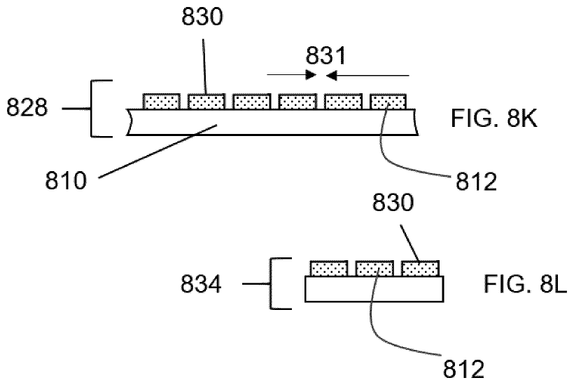

FIGS. 8A through 8L illustrate various steps in an eighth example process for manufacturing an optical element (e.g., a meta-lens). This eighth process uses deep ultraviolet (DUV) lithography to form features in a UV resist layer. The process steps associated with FIGS. 8A-8C can be substantially the same as the process steps associated with FIG. 2A-2C. Likewise, the process steps associated with FIGS. 8H-8J can be substantially the same as the process steps associated with FIGS. 2G-2I.

FIG. 8A shows a substrate 810 (e.g., a glass wafer) having a high-refractive index (HRI) layer 812 deposited on one side of the substrate. The HRI layer has an index of refraction in the range of 2-4. As shown in FIGS. 8B and 8C, respectively, a thin liftoff resist layer 813 is deposited on the HRI layer 812, and a UV resist layer 814 is deposited on the liftoff layer 813. The layer 814 can be deposited, for example by spin coating. The spin speed can be, for example, in the range of 2000 to 7000 rotations per minute (rpm), depending on the particular resist used and the degree to which the resist is diluted in organic solvent. The resist layer 814 can be heated to drive off excess organic solvent. In some instances, the resist layer 814 is deposited to a final thickness in the range of 50-500 nm. The UV resist layer 814 can be a resist that hardens when exposed to ultraviolet (UV) radiation.

In some implementations, the liftoff resist layer 813 can be omitted. However, because the UV resist layer 814 may have relatively high chemical resistance after exposure to UV radiation, it can be advantageous to provide a separate liftoff resist layer 813 to facilitate subsequent processing steps, including removal of the resist layer 814.

Next, as shown in FIG. 8D, portions of the resist layer 814 are exposed to UV radiation using a DUV tool 840. FIG. 8E indicates portions 814A of the resist 814 that are exposed to the UV radiation, and portions 814B that are unexposed. The resist layer 814 then is developed using, for example, a suitable solvent, such that the exposed portions 814A are removed. As shown in FIG. 8E, a residual layer 820 composed of the liftoff resist layer 813 also remains on the surface of the HRI layer 812.

Exposed portions of the residual layer 820 (i.e., exposed portions of the liftoff resist layer 813) are removed, for example, with directional oxygen plasma using a high-vacuum tool or using a barrel asher. The residual layer 820 should be removed at a highly controlled rate (e.g., removed at a rate of 0.1 to 5 nm per second). The result, shown in FIG. 8G, is an unfinished, intermediate wafer 822, which includes a pattern of resist, (e.g., the resist layer material 814B and the underlying portions 813A of the liftoff layer). In some cases, the intermediate wafer 822 of FIG. 8G (or the intermediate wafer of FIG. 8F) may be transferred to another facility or provided to another fabrication facility for further processing. That is, in some instances, a particular fabrication facility may be able to conduct the DUV processing step of FIG. 8D, but not have the capability to process the wafer further into a final optical element or component as described in connection with FIGS. 8H-8L.

As shown in FIG. 8H, a hardmask material 824 then is deposited on the exposed upper surfaces of the resist 814B and the HRI layer 812. In the illustrated example, a high-vacuum tool can be used to deposit the hardmask 824 material (e.g., deposition can be by e-beam deposition or by thermal deposition with a high-vacuum). The high vacuum enables directional deposition of the hardmask material which is needed so that the sidewalls 826 of the resist 814B preferably are not covered in hardmask material.

Next, the resist 814B, along with the portions of the hardmask material 824A that are on the resist layer, is lifted off. This lift-off process can be performed, for example, in a beaker using a solution such as an organic solvent such as acetone. Sonic/ultrasound can be applied to facilitate the liftoff process. As indicated by FIG. 8I, the portions 824A of the hardmask material that were deposited on the surface of the HRI layer 812 remain even after the lift-off process.

As shown in FIG. 8J, the HRI layer 812 then is etched, for example, using inductively coupled plasma (ICP). The hardmask 824A serves as a mask so that the HRI layer 812 is etched selectively. A high-bias (i.e., highly directional) plasma should be used to obtain trenches 826 having substantially vertical sidewalls in the etched HRI layer 812. In some implementations, if the HRI layer 812 is composed of silicon, then C₄F₈ and SF₆ gasses can be used to etch and passivate the silicon simultaneously. In some instances, a HRI layer 812 composed of silicon can be etched using CHF₃, SF₆ and BCl₃. Other etching techniques can be used for some implementations (e.g., etching with O₂ and SF₆ plasma).

Next, the hardmask 824A is removed, for example, by a high-power oxygen and nitrogen plasma in a barrel asher. FIG. 8K shows an example of the resulting metastructure wafer 828, including the meta-atoms 830 formed in the HRI layer 812. Thus, the meta-atoms 830 are composed of the HRI layer material (i.e., a material having a refractive index in the range or 2-4). Further, by comparing FIG. 8K to FIG. 8G, it is apparent that the lateral width of a resist feature 814B corresponds to the distance 831 separating adjacent meta-atoms 830, and the distance separating adjacent resist features 814B corresponds to a lateral dimension of a meta-atom 830.

The metastructure wafer 828 can be separated (e.g., by dicing) into individual optical elements (e.g., metalenses), an example of which is shown in FIG. 8L and identified by reference numeral 834. The individual optical element (e.g., metalens) 834 includes meta-atoms 830, composed of the HRI layer material 812 and supported by the substrate 810. Thus, the meta-atoms 830 of the optical element 834 are composed of a material having a refractive index in the range or 2-4.

In some implementations, the resulting assemblies (e.g., just before or after dicing) can be used a master/tool/mold, for example, to form metalenses or other optical elements in a polymeric material such as by replication. Replication refers to a technique by means of which a given structure is reproduced. In an example of a replication process, a structured surface is embossed into a liquid or plastically deformable material (a “replication material”), then the material is hardened, e.g., by curing using ultraviolet (UV) radiation or heating, and then the structured surface is removed. Thus, a negative of the structured surface (a replica) is obtained.

In some implementations, the substrate (e.g., 110) is removed or is separated from the metastructure. For example, in some implementations, a release layer can be positioned between the substrate (e.g., 110) and the HRI layer (e.g., 112). Subsequently, either before or after dicing, the metastructure can be released from the substrate. Alternatively, in some implementations, etching into the HRI layer (e.g., 112) to form the meta-atoms (e.g., 130) is performed only partially through the HRI layer. The substrate (e.g., 110) then can be ground or lapped away, for example, prior to dicing. Alternatively, the substrate (e.g., 110) may be composed of the same high refractive index material (e.g., amorphous silicon, polycrystalline silicon, crystalline silicon) as the meta-atoms, which may obviate the need to remove or separate the substrate from the metastructure.

Various modifications will be apparent from the foregoing detailed description. Further, features described above in connection with different implementations may, in some cases, be combined in the same implementation. In some instances, the order of the process steps may differ from that described in the particular examples above. Accordingly, other implementations are within the scope of the claims.

1. A method comprising:
providing a hardmask layer on a layer composed of a high refractive index material, the high refractive index material having a refractive index in a range of 2 to 4, the layer composed of the high refractive index material being supported by a substrate;
depositing a resist layer on the hardmask layer;
pressing a surface of a tool into the resist layer, wherein the surface of the tool includes features that are imprinted into the resist layer; and
releasing the tool from the resist layer.

2. The method of claim 1 further including:
after releasing the tool form the resist layer, removing portions of a residual resist layer that is on the hardmask layer, so as to expose first portions of the hardmask layer.

3. The method of claim 2 wherein the portions of the residual resist layer are removed using a directional oxygen plasma.

4. The method of claim 1 further including:
selectively etching the hardmask layer to expose first portions of the layer composed of the high refractive index material; and
selectively etching the exposed first portions of the layer composed of the high refractive index material to form trenches therein.

5. The method of claim 4 further including:
after selectively etching the hardmask layer and selectively etching the exposed first portions of the layer composed of the high refractive index material, removing remaining portions of the resist layer and the hardmask layer so as to expose second portions of the layer composed of the high refractive index material, wherein the second portions of the layer composed of the high refractive index material define optical meta-atoms on the substrate.

6. The method of claim 4 wherein selectively etching the exposed first portions of the layer composed of the high refractive index material includes using an inductively coupled plasma, wherein remaining portions of the resist layer and the hardmask serve as a mask while etching the layer composed of the high refractive index material.

7. The method of claim 1 wherein the layer composed of the high refractive index material is composed of a material selected from a group consisting of: amorphous silicon, polycrystalline silicon, crystalline silicon, silicon nitride, titanium dioxide, and alumina.

8. The method of claim 1 wherein the hardmask material is composed of a material selected from a group consisting of: chrome, titanium, aluminum, silicon nitride and silicon dioxide.

9. The method of claim 5 wherein the meta-atoms and the substrate are composed of a same material as one another.

10. An apparatus comprising:
a substrate;
a layer composed of a high refractive index material and disposed on the substrate, the high refractive index material having a refractive index in a range of 2 to 4;
a hardmask layer disposed on the layer composed of the high refractive index material;
a resist layer disposed on the hardmask layer, wherein the resist layer has features imprinted therein.

11. The apparatus of claim 10 wherein the layer composed of the high refractive index material is composed of a material selected from a group consisting of: amorphous silicon, polycrystalline silicon, crystalline silicon, silicon nitride, titanium dioxide, and alumina.

12. The apparatus of claim 10 wherein the hardmask material is composed of a material selected from a group consisting of: chrome, titanium, aluminum, silicon nitride and silicon dioxide.

13. A method comprising:
providing a hardmask layer on a layer composed of a high refractive index material, the high refractive index material having a refractive index in a range of 2 to 4, the layer composed of the high refractive index material being supported by a substrate;
depositing a UV resist layer on the hardmask layer;
selectively exposing first portions of the UV resist to UV radiation;
developing the resist after exposing the first portions of the UV resist to the UV radiation; and
selectively removing either the first portions of the UV resist that were exposed to the UV radiation or second portions of the UV resist that were not exposed to the UV radiation.

14. The method of claim 13 including using a deep ultra-violet lithography tool to selectively expose the first portions of the UV resist to the UV radiation.

15. The method of claim 13 further including:
selectively etching the hardmask layer to expose first portions of the layer composed of the high refractive index material; and
selectively etching the exposed first portions of the layer composed of the high refractive index material to form trenches therein.

16. The method of claim 15 further including:
after selectively etching the hardmask layer and selectively etching the exposed first portions of the layer composed of the high refractive index material, removing remaining portions of the resist layer and the hardmask layer so as to expose second portions of the layer composed of the high refractive index material, wherein the second portions of the layer composed of the high refractive index material define optical meta-atoms on the substrate.

17. The method of claim 15 wherein selectively etching the exposed first portions of the layer composed of the high refractive index material includes using an inductively coupled plasma, wherein remaining portions of the resist layer and the hardmask serve as a mask while etching the layer composed of the high refractive index material.

18. The method of claim 13 wherein the layer composed of the high refractive index material is composed of a material selected from a group consisting of: amorphous silicon, polycrystalline silicon, crystalline silicon, silicon nitride, titanium dioxide, and alumina.

19. The method of claim 13 wherein the hardmask material is composed of a material selected from a group consisting of: chrome, titanium, aluminum, silicon nitride and silicon dioxide.

20. The method of claim 16 wherein the meta-atoms and the substrate are composed of a same material as one another.

21. An apparatus comprising:
a substrate;
a layer composed of a high refractive index material and disposed on the substrate, the high refractive index material having a refractive index in a range of 2 to 4;
a hardmask layer disposed on the layer composed of the high refractive index material;
a resist layer disposed on the hardmask layer, wherein the resist layer defines a pattern of features on the hardmask layer.

22. The apparatus of claim 21 wherein the layer composed of the high refractive index material is composed of a material selected from a group consisting of: amorphous silicon, polycrystalline silicon, crystalline silicon, silicon nitride, titanium dioxide, and alumina.

23. The apparatus of claim 21 wherein the hardmask material is composed of a material selected from a group consisting of: chrome, titanium, aluminum, silicon nitride and silicon dioxide.
